(19) United States
(12) Patent Application Publication
(10) Pub. No.: US 2013/0068279 A1
(43) Pub. Date: Mar. 21, 2013

(54) PHOTOVOLTAIC MODULE INTERLAYER

(71) Applicants: Benyamin Buller, Perrysburg, OH (US); Wenlai Feng, Perrysburg, OH (US); Casimir Kotarba, Perrysburg, OH (US); David Eaglesham, Perrysburg, OH (US); Brian E. Cohen, Perrysburg, OH (US)

(72) Inventors: Benyamin Buller, Perrysburg, OH (US); Wenlai Feng, Perrysburg, OH (US); Casimir Kotarba, Perrysburg, OH (US); David Eaglesham, Perrysburg, OH (US); Brian E. Cohen, Perrysburg, OH (US)

(21) Appl. No.: 13/614,021

(22) Filed: Sep. 13, 2012

Related U.S. Application Data
(60) Provisional application No. 61/535,213, filed on Sep. 15, 2011.

(51) Int. Cl. H01L 31/042

(52) U.S. Cl. 136/244

(57) ABSTRACT

An interlayer for a photovoltaic device can include a base material and a filler material. The filler material can contain a flame retardant material, a desiccant material, a pigment, an inert material, or any combination thereof.

### CROSS REFERENCE TO RELATED APPLICATION

This application claims priority to Provisional Application No. 61/535,213, filed on Sep. 15, 2011, the disclosure of which is incorporated by reference in its entirety.

### TECHNICAL FIELD

The present invention relates to a photovoltaic module having an interlayer.

### BACKGROUND

A photovoltaic module converts solar radiation to electrical current. This conversion occurs within a plurality of layers formed between a transparent front superstrate and a protective back cover. The plurality of layers can include an n-type semiconductor window layer adjacent to a p-type semiconductor absorber layer, thereby forming a p-n junction. When the module is exposed to sunlight, photons pass through the window layer and are absorbed near the p-n junction. Consequently, photo-generated electron-hole pairs are created. Movement of the electron-hole pairs is promoted by a built-in electric field, thereby producing electrical current.

The module may include a front contact layer on the semiconductor window layer side of the module and a back contact layer on the absorber layer side of the module. During light exposure, current may flow through a circuit connecting the front and back contact layers. For improved reliability, it may be desirable to include an interlayer between the back contact layer and the back cover of the module. And, with some photovoltaic module configurations, interlayer may also be present over the light incident surface of the solar cell assembly if the semiconductor set is deposited onto the top of the substrate material (as opposed to depositing onto the inner surface of the superstrate).

### DESCRIPTION OF DRAWINGS

FIG. 1 is a top perspective view of a portion of a photovoltaic device.

FIG. 2 is a bottom perspective view of a portion of a photovoltaic device.

FIG. 3 is a cross-sectional side view of the module in FIG. 1 taken along section A-A.

FIG. 4A is an exploded view of an embodiment of a thin film photovoltaic module.

FIG. 4B is an exploded view of another embodiment of a thin film photovoltaic module.

FIG. 4C is an exploded view of yet another embodiment of a thin film photovoltaic module.

FIG. 5 is a cross-sectional side view of an example interlayer.

FIG. 6 is a cross-sectional side view of an example interlayer.

FIG. 7 is a cross-sectional side view of an example multilayered interlayer.

FIG. 8 is a cross-sectional side view of an example multilayered interlayer.

FIG. 9 is a cross-sectional side view of an example multilayered interlayer.

### DETAILED DESCRIPTION

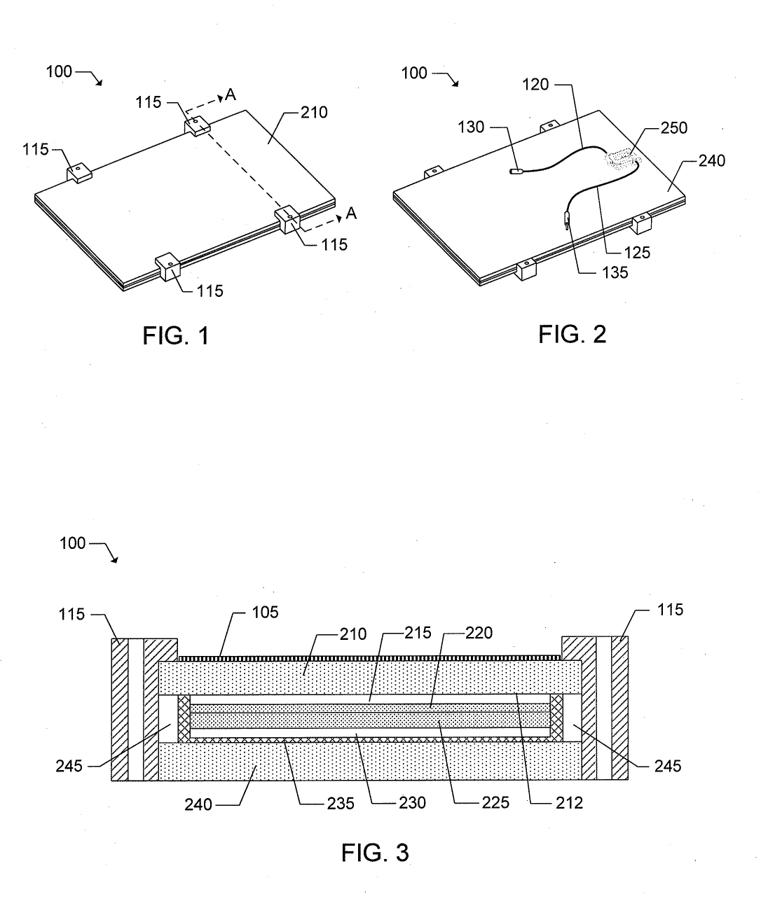

A top perspective view of an exemplary photovoltaic (PV) module 100 is shown in FIG. 1. The module 100 is oriented to receive sunlight through the superstrate layer 210. The sunlight is then converted to electricity within the module using semiconductors. To facilitate this conversion process, the module 100 can include a plurality of PV cells formed on or proximal to the superstrate layer 210. The cells can be connected in series, parallel, or a combination thereof depending on the desired electrical output from the module 100. The module 100 may be fastened to a photovoltaic array (not shown) using a plurality of mounting brackets 115 or through other means.

A bottom perspective view of the module 100 is shown in FIG. 2. To permit interconnection of the module 100 to other electrical devices, the module may include a junction box 250 mounted on the back cover 240. A first and second cable 120, 125 having a first and second connector 130, 135, respectively, may extend from the junction box 250 and may allow for easy connection to another module or other electrical component in a photovoltaic array.

The PV module construction 100 can include a semiconductor stack with a plurality of layers. FIG. 3 shows a cross-sectional view of the module taken along section A-A, which reveals some possible component layers. The plurality of layers can include a front contact 215 formed adjacent to the superstrate layer 210, a semiconductor window layer 220 formed adjacent to the front contact 215, a semiconductor absorber layer 225 formed adjacent to the window layer 220, and a back contact layer 230 formed adjacent to the absorber layer 225.

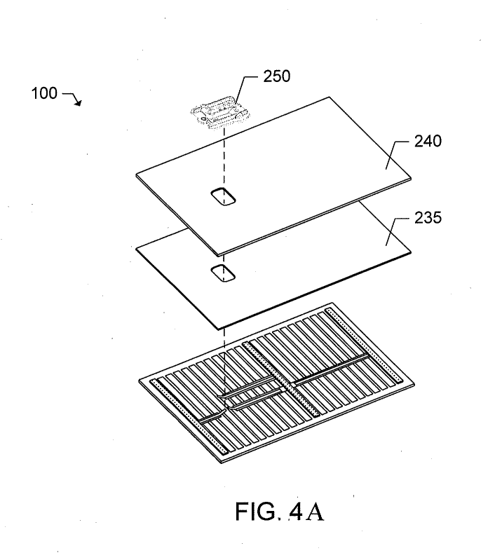

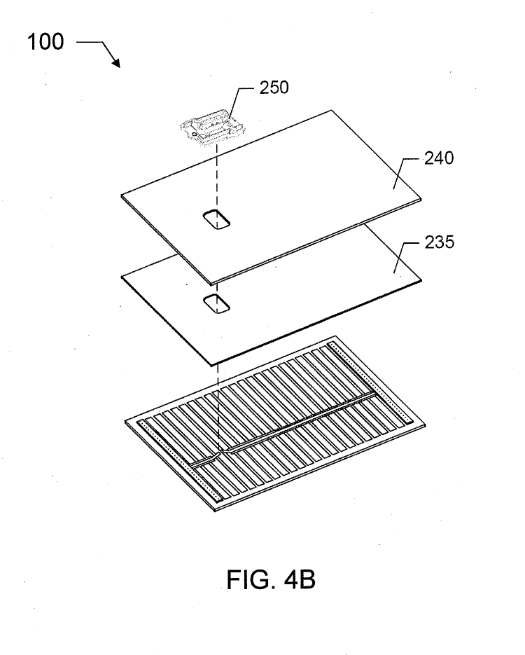

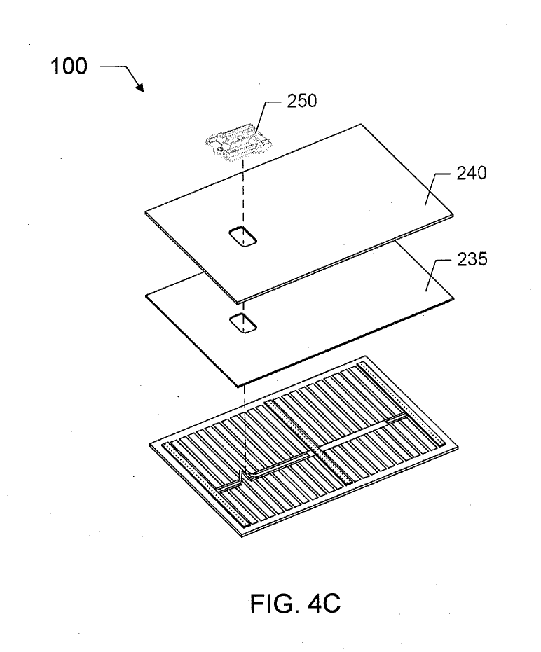

As shown in the exploded view of the modules 100 in FIGS. 4A-4C, after the plurality of layers are formed adjacent to the superstrate layer 210, an interlayer 235, which is described in further detail below, may be added to the module 100, and a back cover 240 may be placed adjacent to the interlayer 235. The back cover 240, also known as a substrate, together with superstrate layer 210 acting as a front cover, can protect the plurality of layers therebetween from moisture ingress and/or physical damage.

The superstrate layer 210 can be the outermost layer of the module 100 and may be exposed to a variety of temperatures and forms of precipitation. The superstrate layer 210 may also be the first layer that incident light encounters upon reaching the module 100. It is, therefore, desirable to select a material for the superstrate layer 210 that is both durable and highly transparent. For these reasons, the superstrate layer 210 may include, for example, borosilicate glass, soda lime glass, or float glass. In particular, it may be desirable to select a type of glass having low iron content to reduce tinting and improve the clarity of the glass.

The superstrate layer 210 may include an outer surface and an inner surface. The superstrate layer 210 may include an anti-reflective (AR) coating 105 adjacent to the outer surface to increase light transmission through the superstrate layer 210 and increase power production. The AR coating 105 may be a single layer or a plurality of layers. For instance, the AR coating 105 may be a stack of layers. The AR coating 105 may include any suitable material such as, for example, magnesium fluoride (MgF2), fluorocarbon based polymers, fluorosilicon-based polymers, or porous materials. Suitable fluorocarbon based polymers may include polyvinylfluoride (PVF), polyvinylidene fluoride (PVDF), polytetrafluoroethylene (PTFE), polychlorotrifluoroethylene (PCTFE), perfluoroalkoxy polymer (PFA), fluorinated ethylene-propylene (FEP), polyethylenetetrafluoroethylene (ETFE), polyethylenechlorotrifluoroethylene (ECTFE), and perfluoropolyether (PFPE). Suitable porous materials may include aluminum oxide, titanium dioxide, magnesium oxide, silicon monoxide, silicon dioxide, or tantalum pentoxide. The AR coating 105 may have a thickness ranging from about 0.1 microns to about 1.0 micron.

The front contact layer 215, which can include a transparent conductive oxide (TCO) stack, may be formed adjacent to the superstrate layer 210. The TCO stack 215 may include a stack of layers adjacent to the superstrate layer 210. For example, the front contact layer 215 may include a barrier layer adjacent to the superstrate layer, a transparent conductive oxide (TCO) layer adjacent to the barrier layer, and a buffer layer adjacent to the TCO layer. The TCO stack 215 may be formed through a series of manufacturing steps where each successive layer is formed adjacent to a previous layer on the module 100.

The barrier layer may lessen or prevent diffusion of sodium ions or other contaminants from the superstrate layer 210 to other layers in the module 100. Diffusion of sodium ions may be promoted by leakage current or electromagnetic field effects. The barrier layer may include any suitable material such as, for example, silicon aluminum oxide (SiAlxOy), silicon oxide (SiO2), tin oxide (SnO), or a combination thereof. The barrier layer may have a thickness ranging from about 100 A to about 3000 A. Preferably, the barrier layer may have a thickness ranging from about 250 A to about 750 A.

The TCO layer may be formed adjacent to the barrier layer. It is desirable to select a material that is highly conductive for the TCO layer. Also, similar to other layers in the module 100 that transmit light, it is also desirable to select a material that is highly transparent, since solar radiation must pass through the TCO layer to reach the active region within the module 100. To achieve high conductivity and high transparency, the TCO layer may include any suitable material such as, for example, tin oxide (SnO), cadmium stannate (Cd2SnO4), tin-doped indium oxide, fluorine-doped tin oxide (SnO:F), cadmium tin oxide, cadmium indium oxide (CIO), aluminum zinc oxide (ZAO), or a combination thereof. The TCO layer may have a thickness ranging from about 500 A to about 5000 A. Preferably, the TCO layer may have a thickness ranging from about 3500 A to about 4500 A.

As noted above, the front contact layer 215 can optionally include a buffer layer. The buffer layer may be formed adjacent to the TCO layer. The buffer layer can be a very thin layer of a material with high chemical stability and transparency. Examples of suitable materials include silicon dioxide, indium oxide, dialuminum trioxide, titanium dioxide, diboron trioxide, zinc oxide, zinc tin oxide, tin oxide, and other similar materials. The buffer layer can also serve to isolate the TCO layer electrically and chemically from the semiconductor window layer 220. By doing so, the buffer layer can prevent reactions from occurring between adjacent layers that could negatively impact performance and stability of the module. The buffer layer can also provide a surface for accepting deposition of the window layer 220. The buffer layer may have a thickness ranging from about 50 A to about 2000 A. Preferably, the thickness of the buffer layer may range from about 500 A to about 1000 A.

The semiconductor window layer 220 may be an n-type semiconductor layer and may be positioned adjacent to the TCO stack 215. The semiconductor window layer 220 may include a thin layer of cadmium sulfide (CdS). The thickness of the semiconductor window layer 220 may range from about 100 A to about 1000 A. Preferably, the thickness of the semiconductor window layer 220 may range from about 200 A to about 400 A. The semiconductor window layer 220, and other layers described herein, may be formed using any suitable thin-film deposition technique such as, for example, physical vapor deposition, atomic layer deposition, laser ablation, chemical vapor deposition, close-spaced sublimation, electrodeposition, screen printing, DC pulsed sputtering, RF sputtering, AC sputtering, chemical bath deposition, or vapor transport deposition.

A semiconductor absorber layer 225 may be formed adjacent to the semiconductor window layer 220. The semiconductor absorber layer 225 may be a p-type semiconductor and may include any suitable material such as, for example, cadmium telluride (CdTe), cadmium selenide, amorphous silicon, copper indium (di)selenide (CIS), or copper indium gallium (di)selenide (CIGS). The semiconductor absorber layer 225 may be deposited using any suitable deposition technique such as, for example, physical vapor deposition, sputtering, atomic layer deposition, laser ablation, chemical vapor deposition, close-spaced sublimation, electrodeposition, or screen printing. The semiconductor absorber layer 225 may have a thickness ranging from about 1 μm about 10 μm. Preferably, the semiconductor absorber layer 225 may have a thickness ranging from about 2 μm to about 5 μm. The semiconductor absorber layer 225 may be formed using any suitable thin-film deposition technique such as, for example, physical vapor deposition, atomic layer deposition, laser ablation, chemical vapor deposition, close-spaced sublimation, electrodeposition, screen printing, DC pulsed sputtering, RF sputtering, AC sputtering, chemical bath deposition, or vapor transport deposition.

In general, the window layer 220 and the absorber layer 225 can include, for example, a binary semiconductor such as a group II-VI, III-V or IV semiconductor, such as, for example, ZnO, ZnS, ZnSe, ZnTe, CdO, CdS, CdSe, CdTe, MgO, MgS, MgSe, MgTe, HgO, HgS, HgSe, HgTe, AlN, AlP, AlAs, AlSb, GaN, GaP, GaAs, GaSb, InN, InP, InAs, InSb, TlN, TlP, TlAs, TlSb, or a combination thereof. An example of a window layer 220 and an absorber layer 225 can include cadmium sulfide (CdS) coated by a layer of cadmium telluride (CdTe).

A p-n junction may be formed where the semiconductor absorber layer 225 abuts the semiconductor window layer 220. When the photovoltaic module 100 is exposed to sunlight, photons may be absorbed within the p-n junction region. As a result, photo-generated electron-hole pairs may be created. Movement of the electron-hole pairs may be promoted by a built-in electric field, thereby producing current. Current may flow between a first cable 120 connected to the front contact layer 215 and a second cable 125 connected to a back contact layer 230. The back contact layer 230 may be formed or deposited onto the semiconductor absorber layer 225 to act as a back electrode. The back contact layer 230 may include one or more highly conductive materials. For example, the back contact layer 230 may include molybdenum, aluminum, copper, silver, gold, or any combination thereof. A back contract can be a metal layer, such as a single elemental layer or layers from multiple elements to increase photovoltaic cell efficiency.

To enclose the module 100, a back cover 240, also referred to as a substrate or as cover glass, can be used. As noted, the back cover 240 and superstrate layer 210, acting as a front cover, can protect the various layers of the PV module from exposure to moisture and other environmental hazards. With respect to composition, the back cover 240 can include any suitable protective material such as, for example, borosilicate glass, float glass, soda lime glass, carbon fiber, or polycarbonate. Alternately, the back cover 240 may be any suitable material such as such as a polymer-based back sheet.

To protect the module 100 from moisture ingress, an edge sealant 245 may be added around the perimeter of the module 100 between back cover 240 and superstrate layer 210 and may include any suitable material such as butyl rubber. The edge sealant 245 may also serve as an adhesive that bonds the superstrate 210 to the back cover 240.

In certain thin film photovoltaic modules 100, an interlayer 235 can be formed between the back cover 240 and the above-mentioned plurality of layers. For example, the interlayer 235 may be formed over the back contact layer 230. The interlayer 235 may serve at least three important functions. First, the interlayer 235 may serve as a moisture barrier between the back cover 240 and the plurality of photoelectrically active layers. By being a moisture barrier, the interlayer 235 may prevent moisture-induced corrosion from occurring inside the module 100. This, in turn, may increase the module's life expectancy.

Second, the interlayer 235 may serve as an electrical insulator between the electrically conductive core of the module and any accessible points exterior to the module. For example, the interlayer 235 may limit or prevent leakage current from passing from the back contact 230 through the back cover 240 of the module.

Third, the interlayer 235 may serve as a bonding agent that attaches the back cover 240 to the rest of the module 100. During manufacturing, a lamination process may heat the interlayer 235 under vacuum to allow the material to wet-out any adjacent adherent surfaces, and in some cases initiate a cross-linking reaction. This process may promote bonding between the interlayer 235 and the back cover 240 as well as between the interlayer and the back contact layer 230. The interlayer 235 may, therefore, serve as a bonding agent within the module 100. The interlayer may include any suitable material such as, for example, ethylene (EVA), polyvinyl butyral (PVB), polydimethylsiloxane (PDMS), polyiso-butylene (PIB), polyolefin, thermoplastic polyurethane (TPU), polyurethane, epoxy, silicone, ionomer, or a combination thereof.

In known modules, the interlayer 235 may be a single-ply of polymeric material, such as ethylene vinyl acetate (EVA). This polymeric interlayer is known to satisfy the above-mentioned functions and perform adequately. However, this polymeric material constitutes a significant portion of module's total cost, which, in turn, constitutes a significant portion of a PV array's total cost. Thus, to improve the cost-competitiveness of PV arrays against other forms of electrical power generation, it is desirable to seek a lower cost alternative to an interlayer formed solely from conventional polymeric materials. It may also be desirable to increase the functionality of the interlayer through the introduction of flame retardants, desiccants, pigmentation, or a combination thereof to improve the module's performance, durability, affordability, appearance, or safety.

In one example, an improved interlayer 235 for a photovoltaic module 100 can include a base material and a filler material. The base material may include any suitable polymeric material. For example, the base material may include ethylene vinyl acetate (EVA), polyvinyl butyral (PVB), polydimethylsiloxane (PDMS), polyisobutylene (butyl/PIB), polyolefin, thermoplastic polyurethane (TPU), polyurethane, epoxy, silicone, ionomer, or a combination thereof. The filler material may be any suitable filler material or combination of materials as described herein. For example, the filler material may be a flame retardant material, a desiccant material, an inert material, or a pigment. Likewise, the filler system may include any combination of these types of materials, thereby providing additional functionality to the interlayer 235. Examples of various types of filler systems are discussed in greater detail below.

The filler material may be a low-cost filler material introduced to displace high-cost polymeric materials. In one example, a portion of the costly base polymer used to form the interlayer 235 may be replaced with the low-cost filler, which may include an inert filler, pore former, or combination thereof. The low-cost filler may be distributed throughout the interlayer 235 and may be added to the base material during an extrusion process, such as a single or twin-screw extrusion process. Alternately, the low-cost filler may be added during a subsequent manufacturing process after the base material has been formed. Examples of inert filler materials include silicate, clay, nanoclay, calcium oxide, calcium carbonate, aluminum trihydrate (ATH), solid glass spheres, hollow glass spheres, glass fibers, reclaimed polymers, natural polymer, cellulose, or any combination thereof. Similarly, any derivatives or analogues of these materials may also be used to displace the higher cost base material.

In addition to reducing the cost of the filler material, it may also be desirable to increase the functionality of the interlayer 235 through the introduction of flame retardants, desiccants, pigments, or a combination thereof to improve the module's performance, durability, affordability, appearance, and/or safety. Thus, the filler material may include one or more materials with the objective of increasing the functionality and affordability of the interlayer.

The filler material may include a desiccant material to improve the water-trapping capabilities of the interlayer 235. In thin film PV modules, the semiconductor stack (and any adjacent transparent conductive oxides and conductive metal coatings) can be sensitive to moisture. By trapping water that has entered the module 100, the interlayer 235 can prevent the water from reaching portions of the module 100 that may be susceptible to degradation. Suitable desiccant materials may include molecular sieves, aluminum oxide (alumina), silica gel, clay, calcium chloride, calcium oxide, calcium sulfate, or any combination thereof. Some of the aforementioned desiccants are expected to be low cost.

In one example, it may be desirable to select a base material having a low moisture vapor transport rate (MVTR), and the desiccant material can be incorporated into the low-MVTR base material. MVTR is a measure of the passage of water vapor through a substance. The time constant for water ingress depends on both the amount of water that can be held by the desiccant and the rate of ingress. Only after the desiccant is saturated will the moisture-sensitive layers be exposed to appreciable levels of water. It is therefore desirable to include a sufficient amount of desiccant material to prevent saturation from occurring. The amount of desiccant material needed to prevent saturation is dependent on the MVTR of the base material. If the base material has a suitable MVTR, moisture that enters the core of the module may diffuse throughout the interlayer 235, thereby utilizing all of the desiccant material and increasing the amount of moisture the interlayer can retain before reaching saturation. It should be noted that if the MVTR is too high, the base material may admit too much water and may jeopardize the life expectancy of the module via corrosion and degradation. Conversely, if the MVTR is too low, the base material may prevent moisture from passing through the base layer and much of the desiccant material may not be utilized and, therefore, may be ineffective at trapping the moisture. To avoid this result, it can be desirable to modify the MVTR of the base material to achieve a suitable MVTR. By utilizing foamed polymers (open or closed cell) and/or a material filled with a pore former (such as ammonium carbonate), it is possible to modify the mass transport properties of the bulk interlayer material to achieve an appropriate MVTR.

In general, the molecular sieve material can be any suitable material with tiny pores of a precise size that are used to adsorb gases or liquids. Molecules that are small enough to pass through the pores are trapped and adsorbed while larger molecules are not. For example, a water molecule may be small enough to pass through the pores while larger molecules are not. Therefore, water molecules may enter the pores and become trapped, thereby allowing the molecular sieve material to function as a desiccant. Accordingly, the molecular sieve material may extract moisture from within the module and prevent the moisture from causing any further structural damage to the module.

The molecular sieve material may include material such as, for example, calcium oxide, silica gels, or aluminosilicate zeolites with crystalline structures. These crystalline structures may be foamed from a network of silicon, aluminum and oxygen atoms having empty spaces between atoms. These empty spaces define “pores” having dimensions specific to the molecular sieve type involved, where the type is defined by the molecule to be trapped. For example, to effectively trap water molecules, the pores may have an average size ranging from 3 to 5 Angstroms. More preferably, the pores may have an average size ranging from 3 to 4 Angstroms.

The molecular sieve material may have any suitable form. For example, the material may be a powder, a paste, or a plurality of beads or pellets. Whatever the sieve material's form, it may be incorporated into the base material before, during, or after the base material is deposited to form the interlayer 235. However, the molecular sieve material should be incorporated before the base material becomes unworkable.

Fire retardant filler material can be added to the interlayer 235 to improve the module's fire resistance. In the U.S., flammability of PV modules is commonly tested under UL 790, which is a safety standard test for roof coverings. Based on the test results, the module may be assigned to Class A, B, or C. In contrast, component-level materials used in constructing PV modules are commonly tested under UL 94, which tests the flammability of plastic materials for parts in devices and appliances. There are twelve flame classifications assigned to materials based on the results of these small-scale flame tests. Six of the classifications relate to materials commonly used in manufacturing enclosures, structural parts, and insulators found in consumer electronic products. These classifications include 5VA, 5VB, V-0, V-1, V-2, and HB and represent the component material's tendency either to extinguish or to spread the flame once the specimen has been ignited.

It is known that commonly used interlayer materials, such as EVA, have the potential to burn readily if exposed to the proper conditions. Because of this, the interlayer material can be a limiting factor when determining module-level fire resistance under UL 790. Therefore, reducing the flammability of the interlayer is desirable, since it results in improved module ratings under UL 790 in addition to improved component-level ratings under UL 94.

While some PV technologies require an interlayer material with a high level of optical transmittance and a certain refractive index, some do not. For example, thin film PV modules as described herein do not require an optical-grade interlayer material due to the location of the interlayer behind the active semiconductor layers. As a result, a fairly high concentration of a flame retardant material can be added to the interlayer formulation in order to improve the module-level flame resistance without adversely affecting performance of the module.

However, when adding flame retardant materials to the interlayer 235, a practical maximum flame retardant concentration exists. This maximum concentration may be determined, at least in part, by parameters such as rheological characteristics (i.e. viscosity), adhesion strength, cost, post-lamination crosslink density, and processability. In other words, there is a practical limit to how much flame retardant material can be added to the interlayer material before the interlayer 235 begins behaving in ways that may negatively impact manufacturing of the PV module. For instance, as the concentration of flame retardant filler increases, the resulting interlayer's adhesion strength may decrease. At some point, the interlayer 235 will lack adequate bonding strength to attach the back cover to the remainder of the module 100, which, depending on the type of module, may be an important function of the interlayer. At that point, the concentration has exceeded the practical maximum concentration for certain types of PV modules.

A desirable range of flame retardant filler concentration within the base polymer may depend on the types of materials selected. As noted above, suitable base polymer materials may include, for example, ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, ionomer, or a combination thereof. Flame resistant materials may include, for example, halocarbons, aluminum trihydrate (ATH), antimony trioxide, borates, hydrated magnesium carbonate, and non-halogenated hindered amines.

The interlayer 235 formulation may also include a flame retardant synergist, for example, antimony trioxide, di(tert-butylperoxyisopropyl)benzene, 2,3-Dimethyl-2,3-diphenylbutane, dicumyl peroxide, 2,5-dimethyl-2,5-di(tert-butylperoxy)hexane, and tert-butyl cumyl peroxide, which may increase the overall effectiveness of the flame retardant material. As a result, use of the synergist may enable the use of significantly lower amounts of flame retardant agents while maintaining a similar level of flame retardancy. By reducing the amount of flame retardant, the properties of the base polymer may be preserved. As a result, the resulting interlayer material may be suitable for manufacturing while also achieving a desirable module-level fire resistance rating.

Fillers, desiccants, and flame retardants can alter the module's appearance. For example, adding inert fillers, desiccants, and flame retardants may impart color to the interlayer 235, thereby altering the appearance of the module 100. Altering the color of the module may be desirable for performance or aesthetic reasons. In a thin film module 100 as described herein, altering the color of the interlayer 235 may have no effect on its performance. However, altering the color of the interlayer in other types of modules can have a significant impact on performance. For example, in certain types of modules, a white interlayer has the potential to reflect non-converted photons back toward the p-n junction, thereby increasing the conversion efficiency of the module.

With respect to aesthetics, it may be desirable to match the interlayer 235 to the color of a building. For instance, in residential applications, it may be desirable to have an interlayer that is a similar color as the shingles of a roof to reduce visibility of the module. The above-mentioned fillers, desiccants, and flame retardants may allow for certain colors to be imparted to the interlayer. To further increase the variety of attainable colors, it may be desirable to add non-conducting pigments or dyes to the interlayer 235. By doing so, the visibility of the modules can be reduced in a wide variety of installations, such as, for example, in urban installations. Coloration may also be useful for hiding cosmetic defects, if any exist.

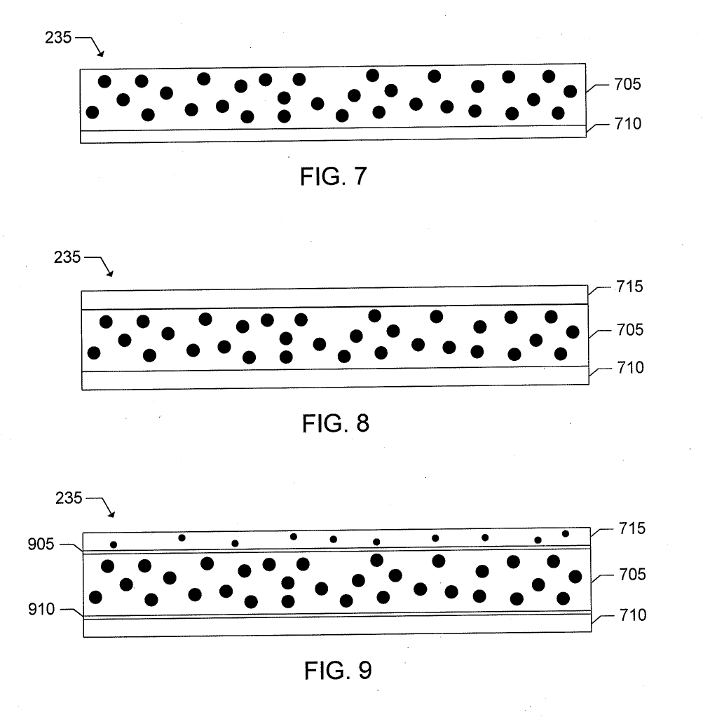

Properties of the interlayer composition can be significantly affected by the addition of one or more filler materials. For example, melt viscosity and other physical properties of the interlayer composition can be significantly affected by the filler type and concentration. As a result, there may be some applications where an interlayer with a high concentration of filler material may have limited processability and insufficient interfacial characteristics. For these situations, a multilayered interlayer can be formed via co-extrusion or any other suitable polymer processing technology. For example, a multilayer interlayer may include a main layer 705 having a relatively higher concentration of filler and one or more additional layers (e.g. 710, 715) having either no filler or a relatively lower concentration of filler, as show by way of example in FIGS. 6-8. The additional layers (e.g 710, 715) may be joined to the main layer by one or more adhesive layers (e.g. 905, 910) or through inherent bonding.

As shown in FIGS. 8 and 9, it may be desirable to sandwich a layer main 705 with a high concentration of filler material between two layers (e.g. 710, 715) having relatively lower concentrations of filler or no filler at all. Through this approach, it may be possible to significantly reduce the overall cost of the interlayer 235 by using an inexpensive main layer 705 containing filler material with adjacent layers (e.g. 710, 715) that have more desirable rheological and adhesion characteristics for manufacturing.

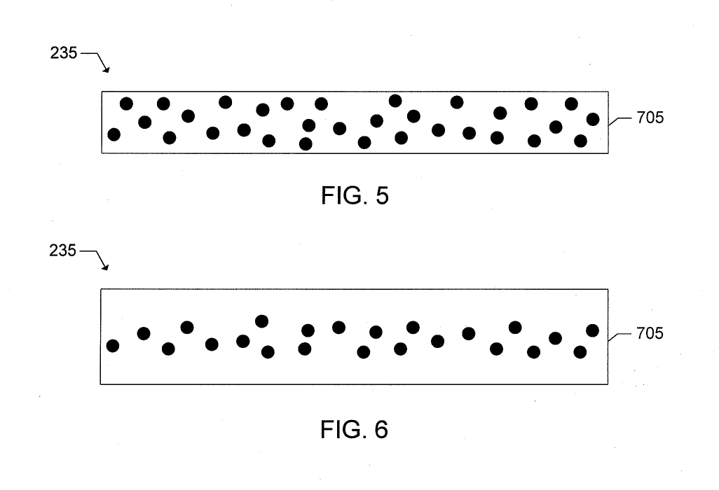

For any of the various types of filler materials described herein, the filler material may be distributed evenly throughout the base material as shown in FIG. 5. Alternately, the filler material may be distributed unevenly throughout the base layer to achieve intended results. For example, it may be desirable to increase the concentration of the filler material near the outer surfaces of the interlayer. In particular, desiccant materials may be more effective if located near an outer surface of the interlayer where the desiccant can easily trap water, as opposed to being encapsulated deep within the base material where water may not necessarily penetrate. In other cases, it may be desirable to increase the concentration of the filler material near the center of the interlayer and decrease the concentration near the outer mating surfaces of the interlayer as shown in FIG. 6. If low-cost filler is introduced to displace higher cost base material, the low-cost material may fail to provide sufficient bonding force between the interlayer and adjacent layers. It may therefore be desirable to reduce the concentration of inert filler near the mating surface of the interlayer to improve the bonding strength near the mating surfaces.

In one aspect, an interlayer for a photovoltaic module may include a base material and a filler material disposed within the base material. The filler material loading level can range from approximately 1% to 75% of the interlayer, by weight. Preferably, the filler material loading level can range from about 10% to 50% of the interlayer, by weight. More preferably, the filler material loading level can range from about 20% to 40% of the interlayer, by weight. The base material may include a material selected from a group consisting of ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, and ionomer. The filler material may include a flame retardant filler material. The flame retardant filler material may include a material selected from a group consisting of halocarbons, aluminum trihydrate (ATH), antimony trioxide, borates, hydrated magnesium carbonate, and non-halogenated hindered amines. The filler material may include an inert filler material. The inert filler material may include a material selected from a group consisting of silicate, clay, nanoclay, calcium oxide, calcium carbonate, aluminum trihydrate (ATH), solid glass spheres, hollow glass spheres, glass fibers, reclaimed polymers, natural polymer, and cellulose. The filler material may include a desiccant filler material. The desiccant filler material may include a material selected from a group consisting of a molecular sieves, aluminum oxide (alumina), silica gel, clay, calcium chloride, calcium oxide, and calcium sulfate. Accordingly, the filler material may include at least one material selected from a group consisting of halocarbons, aluminum trihydrate (ATH), antimony trioxide, borates, hydrated magnesium carbonate, non-halogenated hindered amines, silicate, clay, nanoclay, calcium oxide, calcium carbonate, solid glass spheres, hollow glass spheres, glass fibers, reclaimed polymers, natural polymer, cellulose, a molecular sieve, aluminum oxide (alumina), silica gel, clay, calcium chloride, calcium oxide, and calcium sulfate.

In another aspect, a multilayered interlayer for a photovoltaic module may include a first layer comprising a first base material and a first filler material disposed within the first base material. The multilayered interlayer may also include a second layer adjacent to the first layer. The first filler material may occupy 5% to 95% of the volume of the first layer. The second layer may include a second base material and a second filler material disposed within the second base material. The second filler material may occupy less than 50% of the volume of the second layer. The first base material and the second base material may each include at, least one material selected from a group consisting of ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, and ionomer. The first filler material and the second filler material may each include at least one material selected from a group consisting of halocarbons, aluminum trihydrate (ATH), antimony trioxide, borates, hydrated magnesium carbonate, non-halogenated hindered amines, silicate, clay, nanoclay, calcium oxide, calcium carbonate, solid glass spheres, hollow glass spheres, glass fibers, reclaimed polymers, natural polymer, cellulose, a molecular sieve, aluminum oxide (alumina), silica gel, clay, calcium chloride, calcium oxide, and calcium sulfate.

In yet another aspect, a photovoltaic module may include an interlayer having a base material and a filler material disposed within the base material. The first filler material may occupy 5% to 95% of the volume of the first layer. Alternatively, the filler material loading level can range from approximately 1% to 75% of the interlayer, by weight. Preferably, the filler material loading level can range from about 10% to 50% of the interlayer, by weight. More preferably, the filler material loading level can range from about 20% to 40% of the interlayer, by weight. The base material may include at least one material selected from a group consisting of ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, and ionom. The filler material may include at least one material selected from a group consisting of halocarbons, aluminum trihydrate (ATH), antimony trioxide, borates, hydrated magnesium carbonate, non-halogenated hindered amines, silicate, clay, nanoclay, calcium oxide, calcium carbonate, solid glass spheres, hollow glass spheres, glass fibers, reclaimed polymers, natural polymer, cellulose, molecular sieves, aluminum oxide (alumina), silica gel, clay, calcium chloride, calcium oxide, and calcium sulfate.

The apparatus and methods disclosed herein may be applied to any type of photovoltaic technology including, for example, cadmium telluride, cadmium selenide, amorphous silicon, copper indium (di)selenide (CIS), and copper indium gallium (di)selenide (CIGS). As another example, for modules featuring either silicon wafer cells or a thin film device on metal foil, an interlayer as described above could be arranged on the non-light incident side of the cells. Several of these photovoltaic technologies are discussed in U.S. patent application Ser. No. 12/572,172, filed on Oct. 1, 2009, which is incorporated by reference in its entirety.

Photovoltaic devices can include multiple layers (or coatings) created on a superstrate or substrate. Each layer may in turn include more than one sub-layer or film. Additionally, each sub-layer can cover all or a portion of the device and/or all or a portion of the layer or substrate underlying the layer. For example, a “layer” can include any amount of any material that contacts all or a portion of a surface. Additionally, any layer can be formed through any suitable deposition technique such as, for example, physical vapor deposition, atomic layer deposition, laser ablation, chemical vapor deposition, close-spaced sublimation, electrodeposition, screen printing, DC pulsed sputtering, RF sputtering, AC sputtering, chemical bath deposition, or vapor transport deposition. Also, the term “photovoltaic device” may include any photovoltaic cell, collection of cells, module, device, or any portion thereof.

Details of one or more embodiments are set forth in the accompanying drawings and description. Other features, objects, and advantages will be apparent from the description, drawings, and claims. Although a number of embodiments of the invention have been described, it will be understood that various modifications may be made without departing from the spirit and scope of the invention. Also, it should also be understood that the appended drawings are not necessarily to scale, presenting a somewhat simplified representation of various features and basic principles of the invention.

What is claimed is:

1. A photovoltaic module comprising
a front cover and a back cover;
a plurality of photovoltaic cells between the front and back covers; and
an interlayer between the plurality of photovoltaic cells and the back cover, said interlayer comprising a base material and a filler material disposed within the base material,
wherein a concentration of the filler material disposed within the base material of a first portion of the interlayer is different from a concentration of the filler material disposed within the base material of a second portion of the interlayer.

2. The photovoltaic module of claim 1, wherein the filler material occupies 20% to 40% of the first portion of the interlayer by weight.

3. The photovoltaic module of claim 1, wherein the concentration of the filler material in the second portion is zero.

4. The photovoltaic module of claim 1, wherein the concentration of the filler material in the second portion is less than the concentration of the filler material in the first portion and wherein the second portion is located at a first side of the interlayer.

5. The photovoltaic module of claim 4, wherein the interlayer further comprises a third portion having a concentration of filler material disposed within the base material that is less than the concentration of filler material in the first portion, and wherein the third portion is located at a second side of the interlayer.

6. The photovoltaic module of claim 5, wherein the concentration of the filler material in the second portion and the third portion is zero.

7. The photovoltaic module of claim 1, further comprising an adhesive layer arranged between the first portion and the second portion.

8. The photovoltaic module of claim 1, wherein the filler of the second portion of the interlayer is different from the filler of the first portion of the interlayer.

9. The photovoltaic module of claim 1, wherein the base material comprises at least one material selected from a group consisting of ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, and ionomer.

10. The photovoltaic module of claim 1, wherein the filler material comprises at least one material selected from a group consisting of halocarbons, aluminum trihydrate (ATH), antimony trioxide, borates, hydrated magnesium carbonate, non-halogenated hindered amines, silicate, clay, nanoclay, calcium oxide, calcium carbonate, solid glass spheres, hollow glass spheres, glass fibers, reclaimed polymers, natural polymer, cellulose, molecular sieves, aluminum oxide (alumina), silica gel, clay, calcium chloride, calcium oxide, and calcium sulfate.

11. The photovoltaic module of claim 1, wherein the filler material comprises a flame retardant filler material.

12. The photovoltaic module of claim 11, wherein the flame retardant filler material comprises a material selected from a group consisting of halocarbons, aluminum trihydrate (ATH), antimony trioxide, borates, hydrated magnesium carbonate, and non-halogenated hindered amines.

13. The photovoltaic module of claim 1, wherein the filler material comprises an inert filler material.

14. The photovoltaic module of claim 13, wherein the inert filler material comprises a material selected from a group consisting of silicate, clay, nanoclay, calcium oxide, calcium carbonate, aluminum trihydrate (ATH), solid glass spheres, hollow glass spheres, glass fibers, reclaimed polymers, natural polymer, and cellulose.

15. The photovoltaic module of claim 1, wherein the filler material comprises a desiccant filler material.

16. The photovoltaic module of claim 15, wherein the desiccant filler material comprises a material selected from a group consisting of molecular sieves, aluminum oxide (alumina), silica gel, clay, calcium chloride, calcium oxide, and calcium sulfate.

17. A multilayered interlayer for a photovoltaic module, the interlayer comprising:
a front cover and a back cover;
a plurality of photovoltaic cells between the front and back covers; and
a first layer between the plurality of photovoltaic cells and the back cover, said first layer comprising a first base material and a first filler material disposed within the first base material at a first concentration; and
a second layer adjacent to the first layer.

18. The multilayered interlayer of claim 17, wherein the first filler material occupies 5% to 95% of the volume of the first layer.

19. The multilayered interlayer of claim 17, wherein the second layer further comprises a second base material and a second filler material disposed within the second base material at a second concentration that is different from the first concentration.

20. The multilayered interlayer of claim 19, wherein the second filler material occupies less than 50% of the volume of the second layer.

21. The multilayered interlayer of claim 19, wherein the first base material and the second base material each comprise at least one material selected from a group consisting of ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, and ionomer.

22. The multilayered interlayer of claim 19, wherein the first filler material and the second filler material each comprise at least one material selected from a group consisting of halocarbons, aluminum trihydrate (ATH), antimony trioxide, borates, hydrated magnesium carbonate, non-halogenated hindered amines, silicate, clay, nanoclay, calcium oxide, calcium carbonate, solid glass spheres, hollow glass spheres, glass fibers, reclaimed polymers, natural polymer, cellulose, a molecular sieve, aluminum oxide (alumina), silica gel, clay, calcium chloride, calcium oxide, and calcium sulfate.

23. The multilayered interlayer of claim 17, wherein the second layer does not include a filler material.

24. The multilayered interlayer of claim 19, wherein the interlayer further comprises a third layer comprising a third base material and a third filler material disposed within the third base material at a third concentration that is different from the first concentration, and wherein the first layer is arranged between the second layer and the third layer.

25. The multilayered interlayer of claim 24, wherein the concentration of the filler material in the second layer and the third layer is zero.

26. The multilayered interlayer of claim 17, further comprising an adhesive layer arranged between the first portion and the second portion.

27. The multilayered interlayer of claim 17, wherein the filler of the second portion of the interlayer is different from the filler of the first portion of the interlayer.

28. The multilayered interlayer of claim 17, further comprising an adhesive layer arranged between the first layer and the second layer.

29. The multilayered interlayer of claim 17, wherein the first filler material and the second filler material each comprise at least one of a flame retardant material and a desiccant material.

30. A photovoltaic module comprising
a multilayer interlayer comprising a base material and a filler material disposed within the base material, the interlayer further comprising:
a first layer having a first concentration of filler material, a first side, and a second side;
a second layer arranged on the first side of the first layer and having a second concentration of filler material; and
a third layer arranged on the second side of the first layer having a third concentration of filler material,
wherein the first concentration is different than the second and third concentrations.

31. The photovoltaic module of claim 30, wherein the second concentration and the third concentration of the filler material is zero.

32. The photovoltaic module of claim 30, wherein the second concentration and the third concentration of the filler material is less than the first concentration of the filler material.

33. The photovoltaic module of claim 30, further comprising a first adhesive layer arranged between the first layer and the second layer and a second adhesive layer arranged between the first layer and the third layer.

34. The photovoltaic module of claim 30, wherein the base material comprises at least one material selected from a group consisting of ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, and ionomer.

35. The photovoltaic module of claim 30, wherein the filler material comprises a flame retardant filler material or a desiccant material.

36. A photovoltaic module comprising
an interlayer comprising a base material and a filler material disposed within the base material,
wherein the base material comprises at least one material selected from a group consisting of ethylene vinyl acetate (EVA), polyvinyl butyral (PVB), polydimethylsiloxane (PDMS), butyl/PIB, polyolefin, thermoplastic polyurethane (TPU), polyurethane, epoxy, silicone, and ionomer, and
wherein the filler material comprises at least one material selected from a group consisting of halocarbons, aluminum trihydrate (ATH), antimony trioxide, borates, hydrated magnesium carbonate, non-halogenated hindered amines, silicate, clay, nanoclay, calcium oxide, calcium carbonate, solid glass spheres, hollow glass spheres, glass fibers, reclaimed polymers, natural polymer, cellulose, a molecular sieve, aluminum oxide (alumina), silica gel, clay, calcium chloride, calcium oxide, and calcium sulfate.

37. The photovoltaic module of claim 36, wherein the filler material occupies approximately 1% to 75% of the interlayer, by weight.

38. The photovoltaic module of claim 36, wherein the filler material occupies approximately 10% to 50% of the interlayer, by weight.

39. The photovoltaic module of claim 36, wherein the filler material occupies approximately 20% to 40% of the interlayer, by weight.
